(19) United States
(12) Patent Application Publication
(10) Pub. No.: US 2025/0259927 A1
(43) Pub. Date: Aug. 14, 2025

(54) FUSIBLE D-FUSE HYBRID BOND STRUCTURE

(71) Applicant: International Business Machines Corporation, Armonk, NY (US)

(72) Inventors: Nicholas Alexander POLOMOFF, Hopewell Junction, NY (US); Mukta Ghate Farooq, HOPEWELL JCT, NY (US)

(21) Appl. No.: 18/440,929

(22) Filed: Feb. 13, 2024

(51) Int. Cl. H01L 23/525

(52) U.S. Cl. CPC H01L 23/5256

(57) ABSTRACT

A hybrid bonded d-fuse structure including a first and second semiconductor builds, hybrid bonded to each other at an interface, a first contact in the first build and at the interface, a second contact in the second semiconductor build and at the interface. A burned connection present or capable of being formed at the interface and connecting the first and second contacts.

### BACKGROUND

The present invention relates generally to the electrical, electronic and computer arts and, more particularly, to joining two semiconductor builds such as chips, dies, wafers, interposers, or combinations thereof together and, further, to anti-fuses and the like.

In hybrid bonding, a permanent bond combines two semiconductor builds, each having a dielectric and embedded metal (e.g., Cu) on the surface. Two semiconductor builds are joined (e.g., two individual wafers that are built separately). These hybrid bonding joining interface surfaces require a “pristine” surface (smooth and flat, possibly with some recesses), more so than required by a standard BEOL dielectric layer undergoing traditional chemical-mechanical planarization (CMP) processing. The surfaces of the two semiconductor builds are purposely designed to align. The term “hybrid” refers to the presence of both metal to metal and dielectric to dielectric bonding. The two semiconductor builds are brought together, and a heat treatment/annealing process is carried out. The oxides bond together and the metals “anneal,” or almost melt, together, thus fusing the interface into a single bonded part (in some instances, seamlessly; i.e., the interface line disappears).

Anti-fuses start as a non-conducting structure, and with application of current and or heat, become conducting. Thus, anti-fuses create an electrical connection that did not previously exist. One type of anti-fuse is known as a D-fuse (dielectric breakdown fuse and/or also known as delta metal fuse); with the application of current, a dielectric breaks down between adjacent conducting lines within the same metal level resulting in these metal lines to contact and fuse together and create an electrical connection within a semiconductor build which horizontally connects circuits (i.e., two-dimensional or 2D) on a substrate level.

### BRIEF SUMMARY

Principles of the invention provide techniques for a fusible structure locate on different semiconductor builds which are hybrid bonded to each other. In one aspect, an exemplary a hybrid bonded D-fuse structure includes a first semiconductor build, a second semiconductor build hybrid bonded to the first semiconductor build to form an interface, a first contact in the first semiconductor build and at the interface, a second contact in the second semiconductor build and at the interface; and a burned connection at the interface and connecting the first and second contacts.

In another aspect, another exemplary hybrid bonded D-fuse structure includes a first semiconductor build, a second semiconductor build hybrid bonded to the first semiconductor build to form an interface, a first contact in the first semiconductor build and at the interface, a second contact in the second semiconductor build and at the interface, a fusible area containing the first and second contacts, and a dummy area laterally surrounding the fusible area, the dummy area containing at least two dummy contact pairs wherein a distance between the first and second contact is less than a distance between the first or second contact and a closest dummy contact.

In still a further aspect, an exemplary method of forming a D-fuse structure, including providing a first semiconductor build (which includes a first surface, a first group of fusible contacts coplanar with the first surface, a first group of dummy contacts coplanar with the first surface, and a first group of last metals below and in electrical contact with the first group of fusible contacts), providing a second semiconductor build (which includes a second surface, a second group of fusible contacts coplanar with the second surface, and a second group of dummy contacts coplanar with the second surface), and hybrid bonding the first surface to the second surface to form an interface.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
Allows turning on of another semiconductor build (e.g. wafer to wafer, die to wafer or die to die).
Allows a for a highly secure structure by placing d-fuses within a circuit that protects certain sensitive data or parts of the chip. The security feature can only be accessible if the d-fuse is activated or switched to be conductive. This access or application of a correct voltage can be gatekept by a password or some sort of coded element. Thusly, the physical d-fuse would only be activated if a correct code or password is entered by the user. Attempting to physically hack or bypass this code/password through application of a voltage would result in not activating the d-fuse device (turning it on) or destroying said device thereby cutting off all connection to accessing the sensitive data.
Allows for dynamic real-time reprogramming and performance tuning of chips. For example, if a subsystem fails, is lagging in response, or consuming too much power, a D-fuse can be burned to make another semiconductor build active in its place.
Allows for redundancy. For example, a lower semiconductor build may have multiple other upper semiconductor builds bonded to it. If a primary upper semiconductor build fails, the D-fuse can be burned to activate to a replacement secondary upper semiconductor build.
Allows one-time programmable read-only memory from one semiconductor build to another hybrid bonded semiconductor build.
Allows program code, on-chip configuration data and cryptographic keys from one semiconductor build to another hybrid bonded semiconductor build.
Allows restrictive programming from one semiconductor build to another hybrid bonded semiconductor build.
Allows for redundant cells for memory repair or lot identification from one semiconductor build to another hybrid bonded semiconductor build.
Allows for a less disruptive (e.g. fewer masks) process semiconductor build by having the D-fuse at the hybrid bond level or the last metal level as opposed to the back end of line level.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1A depicts top view of a semiconductor build surface having an exemplary dummy contact configurations around a fusible area;

FIG. 1B depicts a cross-section of the semiconductor build of FIG. 1A taken along the x-direction;

FIGS. 2A-2C depicts top-view of a semiconductor build surface having various dummy contact configurations;

FIG. 3A depicts cross-sections of first and second substates being flipped in the process of making the hybrid bonded D-fuse structure of FIG. 3B;

FIG. 3B depicts cross-sections of hybrid bonded D-fuse structure pre-burning, in which the fusible area contacts of the semiconductor builds align;

FIG. 4 is an embodiment of FIG. 3B post-burn, in which the distance between adjacent last metal is greater than the distance between adjacent contacts;

FIG. 5 is an embodiment of FIG. 3B post-burn, in which the distance between adjacent last metal is less than the distance between adjacent contacts;

FIGS. 6A and 6B show an embodiment of FIG. 3B pre- and post-burn, in which the distance between adjacent last metal includes an air gap;

FIGS. 7A and 7B depict cross-sections of a hybrid bonded D-fuse structure pre- and post-burning, in which the fusible area contacts of the semiconductor builds do not align.

FIG. 8 is a pictorial view of yet another embodiment of the invention;

FIG. 9 depicts a computing environment according to an embodiment of the present invention (e.g., for implementing a design process such as that of FIG. 17); and

FIG. 10 is a flow diagram of a design process used in semiconductor design, manufacture, and/or test.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

One or more embodiments relate to joining two semiconductor builds such as chips, dies, wafers, interposers, or combinations thereof together and, further, to fuses/anti-fuses incorporated into such joined semiconductor builds. For a particular circuit, electrical connection of the two joined semiconductors builds is not achieved until sufficient current/voltage is applied thereby activating the D-fuse to complete an electrical path from one build to joined build.

An exemplary a hybrid bonded D-fuse structure includes a first semiconductor build 110, a second semiconductor build 210 hybrid bonded to the first semiconductor build to form an interface 240, a first contact in the first semiconductor build and at the interface, a second contact in the second semiconductor build and at the interface; and a burned connection 500 at the interface and connecting the first and second contacts 124. The structure electrically connects, post manufacture, one semiconductor build to another. This can provide many of the beneficial uses described earlier (e.g. security, redundancy, programming, etc.).

Optionally, the first contact and the second contact do not vertically overlap with each other, thereby providing the benefit of relaxed manufacturing and design constraints. The D-fuse structure can also include more contacts 124. For example, a third contact in the second semiconductor build 210 at the interface and spaced apart from the second contact and a fourth contact in the first semiconductor build 110 at the interface 240 and spaced apart from the first contact in which neither of the first and fourth contacts vertically overlap with any of the second or third contacts. A technical benefit is that it enables forming each build individually with the spacing and proximity permitted by manufacturing base rules while at the same time the spacing of the contacts on each build compared to the other build can violate manufacturing processing base rules (since each of different builds do not individually violate base rules). Therefore, the close proximity the contacts need to be able to fuse together across the joining interface on each individual build is achieved without violating the manufacturing process rules of each individual build. In short, it allows forming each semiconductor build with no design rule issues, but when adjoined, the contacts are designed/patterned in a way that the pairing would normally violate base rules. In an additional option, the D-fuse structure includes a first last metal 118 in the first semiconductor build 110 in electrical connection with the first and fourth contacts, and a second last metal 118 in the second semiconductor 210 build in electrical connection with the second and third contacts. This variation allows for large last metals so it can match pattern factors found in other areas of the build to reduce the likelihood of reactive ion etching lag or chemical mechanical polish dishing or similar patterning sensitive processing steps.

Alternatively, the D-fuse structure can also include a third contact in the second semiconductor build 210, and a fourth contact in the first semiconductor build 110 in which the first contact vertically aligns with the third contact to form a first contact pair 304A and in which the wherein the second contact vertically aligns with the fourth contact to form a second contact pair 304B. In this variation, two contact pairs at the interface have the benefit of a stronger interface.

Advantageously, each of the first, second, third and fourth contacts can be in electrical contact with a different last metal 118. This variation allows for large individual last metals that can match pattern factors found in other areas of the build to reduce the likelihood of reactive ion etching lag or chemical mechanical polish dishing or similar patterning sensitive processing steps.

In a further option, the D-fuse structure includes a fusible area 102 containing the first and second contacts, a dummy area 101 laterally surrounding the fusible area, the dummy area containing at least two dummy contact pairs 302. The benefit of a dummy area is to confine potential damage caused by burning the fuse so that adjacent active circuits are not damaged.

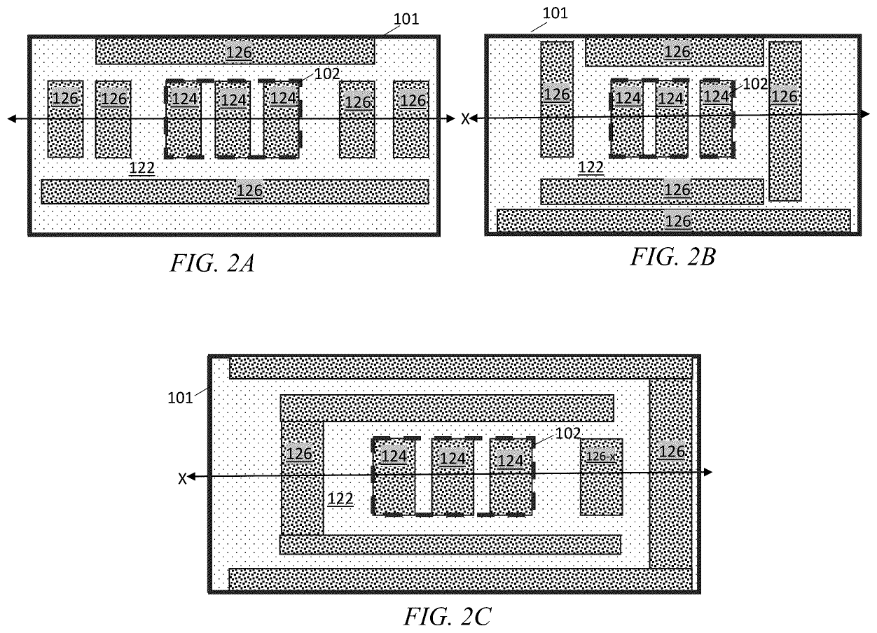

In some embodiments, the D-fuse structure the at least two dummy contact pairs 302 are nested u-shaped structures facing opposite directions (see FIG. 2C). By surrounding the fusible area 102 but not being a continuous ring, the nested u-shaped structure avoids unintentional electrical interference. The dummy contacts pairs 302 also aid in mechanical pinning around a D-fuse structure.

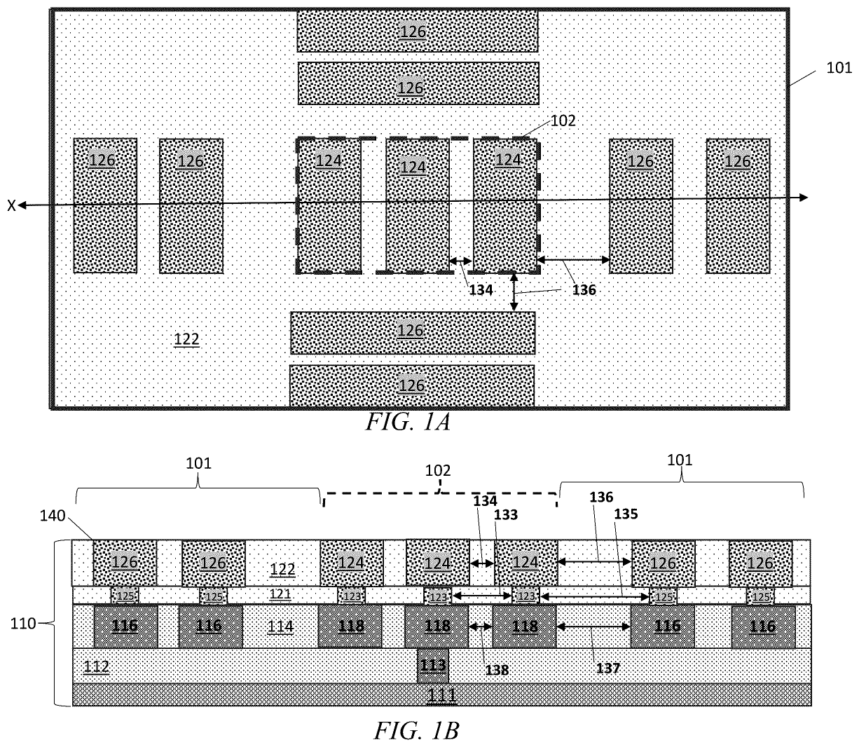

In further options, the D-fuse structure includes a first group of the at least two dummy contact pairs 302 are parallel to the first and second contacts 124 and are on either side of a fusible area 102, and a second group of the at least two dummy contact 126 pairs are perpendicular to the first and second contacts 124 and are on opposite sides of the fusible area 102. (See FIG. 1A). The dummy structures protect adjacent active areas from any fuse burning damage and can serve as dummy patterning for chemical mechanical polishing and help in hybrid bonding. In another option, a distance between the first and second contact 124 is less than a distance between the first or second contact 124 and a closest dummy contact 126. Here, the technical benefit is to aid in burn the fuse in the desired location.

In as second aspect of the invention a hybrid bonded D-fuse structure including a first semiconductor build 110, a second semiconductor build 210 hybrid bonded to the first semiconductor build to form an interface 240, a first contact in the first semiconductor build and at the interface, a second contact in the second semiconductor build and at the interface, a fusible area 102 containing the first and second contacts 124, and a dummy area 101 laterally surrounding the fusible area, the dummy area containing at least two dummy contact pairs 302 wherein a distance between the first and second contact is less than a distance between the first or second contact and a closest dummy contact 126. The structure is capable of electrically connecting one semiconductor build to another, post manufacture. This can provide many of the beneficial uses described earlier (e.g. security, redundancy, programming, etc.) while the dummy areas can provide protection to hardwired circuits of the builds when a burned connection is made.

Optionally, the first contact and the second contact do not vertically overlap with each other, thereby providing the benefit of relaxed manufacturing and design constraints.

In another option the D-fuse structure further includes a third contact in the second semiconductor build at the interface and spaced apart from the second contact, and a fourth contact in the first semiconductor build at the interface and spaced apart from the first contact, in which wherein neither of the first and fourth contacts vertically overlap with any of the second or third contacts. A technical benefit is that it enables forming each build individually with the spacing and proximity permitted by this particular level (within manufacturing base rules) while at the same time the spacing of the contacts on each build compared to the other build can violate manufacturing processing base rules (since different builds it doesn't violate individually). Therefore, close proximity the contacts needed to be able to fuse together across the joining interface on each individual build is achieved without violating the manufacturing process rules of each individual build. In short, it allows forming each semiconductor build with no design rule issues, but when adjoined, the contacts are designed/patterned in a way that the pairing would normally violate base rules.

Optionally, the D-fuse structure can include a first last metal 118 in the first semiconductor build 110 in electrical connection with the first and fourth contacts, a second last metal 118 in the second semiconductor 210 build in electrical connection with the second and third contacts. This variation allows for large last metals so it can match pattern factors found in other areas of the build to reduce the likelihood of reactive ion etching lag or chemical mechanical polish dishing or similar patterning sensitive processing steps. In a further option, the D-fuse structure can include a third contact in the second semiconductor build 210 and a fourth contact in the first semiconductor build 110, in which the first contact vertically aligns with the third contact to form a first contact pair 304A and in which the second contact vertically aligns with the fourth contact to form a second contact pair 304B. In this variation, two contact pairs at the interface have the benefit of a stronger interface. In still a further aspect, an exemplary method of forming a D-fuse structure, including providing a first semiconductor build 110 (which includes a first surface, a first group of contacts 124 coplanar with the first surface 140, a first group of dummy contacts 126 coplanar with the first surface, and a first group of last metals 118 below and in electrical contact with the first group of fusible contacts), providing a second semiconductor build 210 (which includes a second surface, a second group of contacts 124 coplanar with the second surface, and a second group of dummy contacts 126 coplanar with the second surface), and hybrid bonding the first surface to the second surface to form an interface 240. The method results in a structure that is capable, after manufacturing and in the field, of turning on another semiconductor build which can have many of the beneficial uses described earlier (e.g. security, redundancy, programming, etc.).

Optionally, the method further includes forming a burned connection 300 between the first group of fusible contacts at the interface 240. A benefit of interfacial burned contacts is efficient use of chip space and mask levels.

Optionally, the method further includes forming a burned connection 300 between a first group of last metals 118. A benefit of last metal burned connection is efficient use of chip space and mask levels.

Optionally, the first and second groups of contacts 124 can vertically overlap. Optionally, the first and second groups of contacts 124 cannot vertically overlap. The optionality of alignment aids manufacturing by allowing for a larger process window and more flexible design parameters.

Aspects of invention provide techniques for a hybrid bonded D-fuse structure. A hybrid bond structure has a first semiconductor build (e.g. a lower build) having a surface with metal and dielectric portions and a second semiconductor build 210 (e.g. an upper build) having a surface with metal and dielectric portions connected by a hybrid bond joining interface. A “semiconductor build” can be a wafer or a die; thus, the hybrid bonded semiconductor builds can be wafer to wafer, die to die or wafer to die. The semiconductor build surfaces are put in contact and heat is applied to bond the semiconductor builds together. In hybrid bonding, the dielectric portions of the first and second semiconductor builds bond to each other while at the same time metal portions of the first and second semiconductor builds bond to each other. The metal-to-metal bonding can include lower and upper electrical contact bonding pads forming contact pairs and can include lower and upper non-electrical contact bonding pads forming dummy contact pairs FIGS. 1A and 1B depict top down (FIG. 1A) and cross-sections (FIG. 1B) taken at the line “X” of FIG. 1A of a first semiconductor build. Refer to FIG. 1B, which shows a cross-section of a first semiconductor build 110 having one or more of the following levels: a transistor level 111, a back end of line level (“BEOL” level 112) including a BEOL metallization 113 on the transistor level, a last metal level including a last metal interlevel dielectric (last metal ILD 114) and last metal 118, and a contact level including a dielectric 122 and contacts (dummy or not) with an optional etch stop 121 dielectric and via 123. It is the contact level dielectric 122, the dummy contact 126 and, in some embodiments, the contacts 124 that create the hybrid bond between semiconductor builds. Last metal ILD 114, dielectric 122, and etch stop 121 can be silicon oxides, nitrides or combinations of both, Last metal 118 and contacts (dummy or not) may be copper or another suitable conductor.

It will thus be appreciated that in one or more embodiments, the upper and lower semiconductor builds are connected by a hybrid bond joining interface including metal-to-metal bonding of the plurality of upper semiconductor build electrical contact bonding pads with the plurality of lower semiconductor build electrical contact bonding pads, metal-to-metal bonding of the first and second upper semiconductor build non electrical contact bonding pads with the first and second lower semiconductor build non electrical contact bonding pads, and dielectric bonding of the upper semiconductor build insulator layer with the lower semiconductor build insulator layer.

Now continuing, and still referring to FIG. 1B, the semiconductor build can have two areas, a fusible area 102 and a dummy area 101. The fusible area 102 contains contacts 124, and optional vias 123 that have at least one underlying last metal 118 which is connected to the transistor level 111. With the application of current, the fusible area 102 adjacent contacts 124 or adjacent last metals 118 can be burned to each other, creating an electrical connection where one did not previously exist. The dummy area 101 contains dummy contacts 126, and optionally dummy vias 125 and dummy last metal 116. Dummy area 101 structures are not electrically connected to the transistor level 111. The purpose of the dummy contacts 126 is to inhibit damage propagation when a burned connection is made and to prevent undesirable metal fuse connections from being made.

FIG. 1A shows a top-down view of the surface 140 of the first semiconductor build 110. The fusible area 102 is denoted by the dotted line around the contacts 124. Surrounding the fusible area on four sides is the dummy area 101. In the exemplary embodiment of FIG. 1A, there are pairs of dummy contacts 126 on each side of the fusible area 102. FIGS. 2A through 2C depict other exemplary configurations of dummy contacts 126 around a fusible area 102. Referring to FIG. 2A, a pair of dummy contacts 126 in first direction relative to the contacts 124 (for example parallel) extend to a same length of the fusible area 102 while dummy contacts 126 in a second direction (for example perpendicular) can extend beyond a side of the fusible area 102 and can overlap partially or completely with dummy contacts oriented in the first direction. FIG. 2B is another exemplary embodiment of dummy contacts 126 with various extensions relative to the contacts 124 of the fusible area 102 and relative to other dummy contacts 126. FIG. 2C is yet another embodiment in which a pair of u-shaped dummy contacts 126 are nested within each other and face opposite directions to surround the fusible area 102. As can be seen a wide variety of dummy contact 126 configurations, orientations, and combinations are possible: accordingly, FIG. 1A and FIGS. 2A through 2C are by way of illustration and not limiting.

Referring back to FIGS. 1A and 1B, several distances are noted. At the contact level, contact distance 134 denotes the distance between adjacent contacts 124, dummy-contact distance 136 denotes the distance between a contact 124 and its nearest dummy contact 126, via distance 133 denotes the distance between adjacent vias 123, dummy via distance 135 denotes the distance between a via 123 and its nearest dummy via 125, last metal distance 138 denotes the distance between adjacent last metals 118, and dummy-last metal distance 137 denotes the distance between a last metal 118 and its nearest dummy last metal 116. The effect of the relative distances is that the smallest distance, given similar dielectric constant of insulating layers, is the one which in which a burned connection should form upon application of current/voltage. Advantageously, to better control the burn and to conserve space, the contact distance 134 and/or the last metal distance 138 can be less than the process specifications (It is preferred to have the areas where it is desired to have the burned connection to form to be small, therefore, it is acceptable to put adjacent lines or contacts closer proximity to each other than process specifications normally allow).

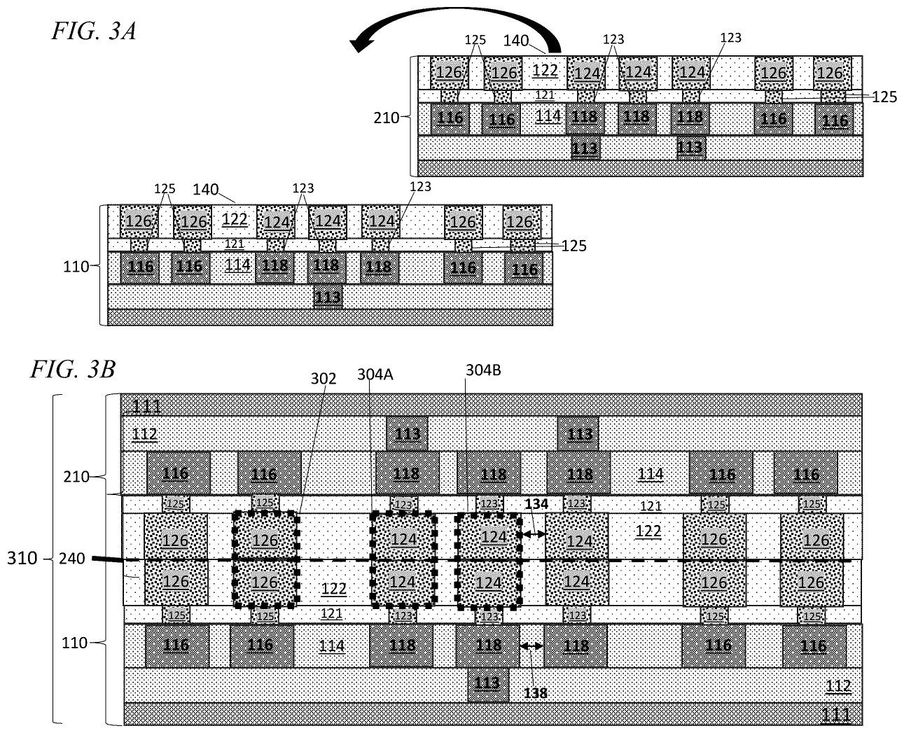

FIGS. 3A and 3B depict two semiconductor builds pre- and post-hybrid bonding, according to an embodiment of the invention. Referring to FIG. 3A, note a first semiconductor build 110 and a second semiconductor build 210 (also shown in FIG. 1B). The second semiconductor build 210 is flipped onto the first semiconductor build 110 so that their surfaces 140 meet to form interface 240 of FIG. 3B. In the embodiment of FIGS. 3A and 3B, the surfaces 140 of the first semiconductor build 110 and the second semiconductor build 210 in the fusible area 102 and dummy area 101 are mirror images, such that contacts 124 and dummy contacts 126 are aligned and in contact with each other (or stated another way, contacts 124 and dummy contacts 126 vertically overlap). Due to the alignment, upon heating the semiconductor builds, hybrid bonding occurs both in the fusible area 102 and the dummy area 101. Specifically, dielectric 122, contacts 124, and dummy contacts 126 of the first semiconductor build 110 and second semiconductor build 210 are bonded at the interface 240. Accordingly, contact pairs 304A and 304B and dummy contact pairs 302, bridging the first semiconductor build 110 and second semiconductor build 210, are formed in the hybrid bonded D-fuse structure 310. Note, in this pre-burning structure of FIG. 3B, the contacts pairs 304A, 304B do not result in an active electrical path to circuits on each semiconductor build. For example, the “A” contact pair 304A is only connected to circuitry (e.g. transistor level 111 and BEOL metallization 112) of the second semiconductor build 210 and is merely connected to a last metal 118 segment which is not connected to any other circuit in the first semiconductor build 110. The opposite is true for the “B” contact pair 304B.

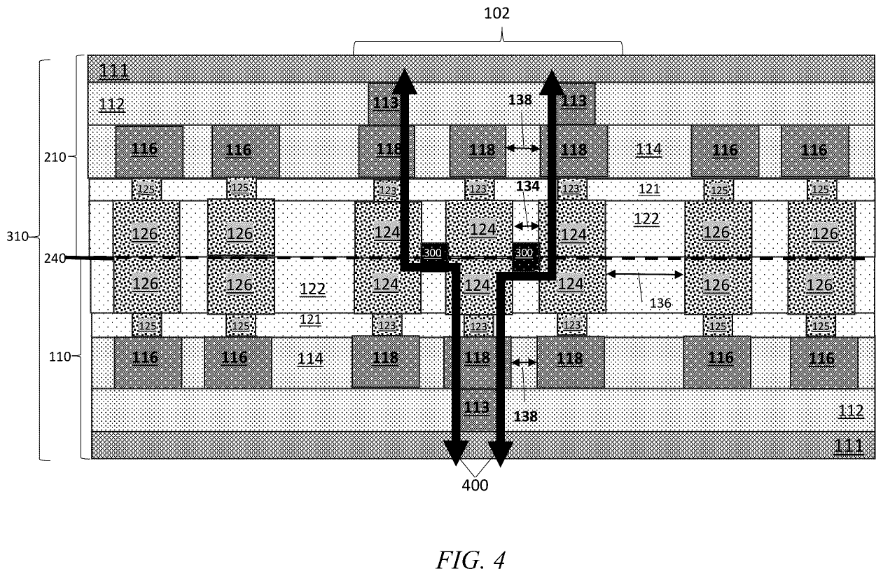

FIG. 4 shows the structure of FIG. 3B after causing an electrical current to flow through the fusible area 102, thus forming a burned connection 300. The current can flow from the first semiconductor build 110 to the second semiconductor build 210 or vice-versa. Any electrical signal (e.g. alternating current) that is sufficient enough to result in the dielectric breakdown and fusing the of the metal contacts together can be used. A voltage can be applied to cause the current flow or a current source can be used. Voltage/current can be applied through one or more of the contacts 124 in a given semiconductor build (e.g. one or both of the contacts 124 connected to BEOL metallization 113 in the second semiconductor build 210). The burned connection 300 is between adjacent contacts because the contact distance 134 is smaller than other distances discussed in conjunction with FIG. 1B; for example, last metal distance 138 or dummy-contact distance 136. The burned connection 300 is formed at the interface 240 and occupies space in the dielectric 122 of the first semiconductor build 110 and the second semiconductor build 210. As indicated by the heavy arrow, the horizontal burned connection 300 now enables a vertical electrical connection 400 of circuitry from the first semiconductor build 110 to circuitry of the second semiconductor build 210.

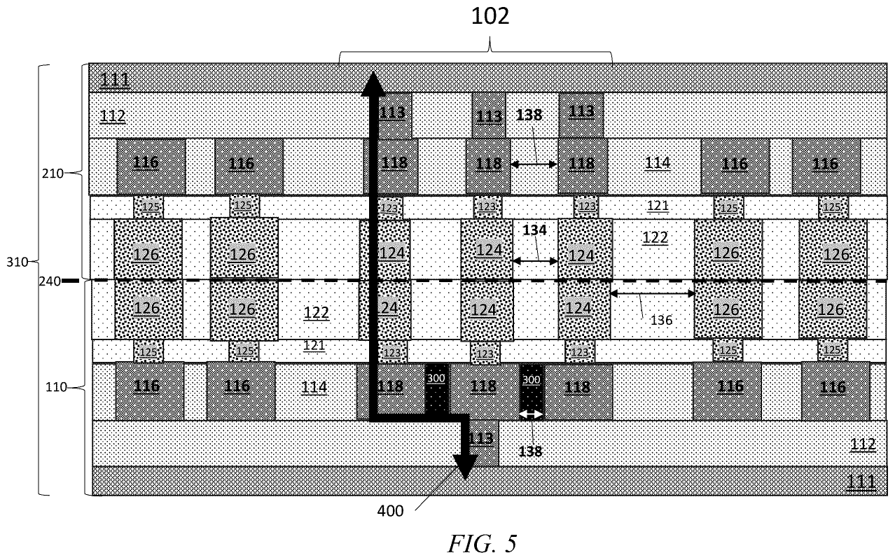

FIG. 5 shows an embodiment of FIG. 3B in which the last metal distance on the first semiconductor build is smaller than contact distance 134 and less than other distances discussed in conjunction with FIGS. 1A and 1B. In such a case, after applying a current/voltage to the fusible area 102, a burned connection 300 is formed in last metal ILD 114 between adjacent last metals 118 of the first semiconductor build 110. As indicated by the heavy arrow, the horizontal burned connection 300 now enables a vertical electrical connection 400 of circuitry from the first semiconductor build 110 to circuitry of the second semiconductor build 210. Note, that while only one vertical electrical connection 400 is depicted in FIG. 5, the embodiment of the depicted burned connection 300 would also connect the other two last metal 118 in the second semiconductor build 210 to the first semiconductor build 110.

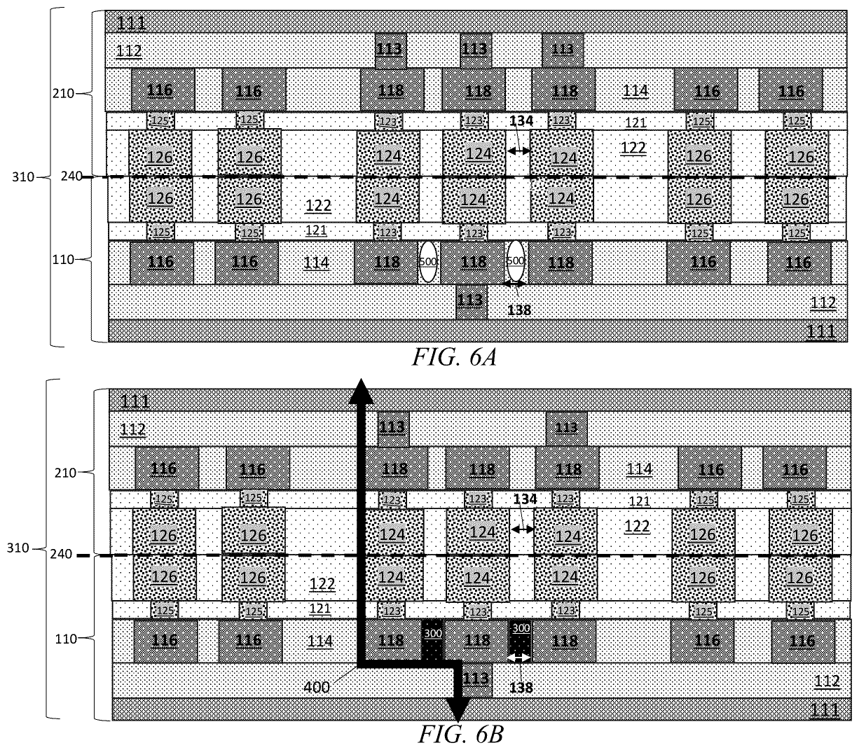

FIG. 6A shows an embodiment of FIG. 3B in which the last metal distance 138 includes an air gap 500 and optionally some last metal ILD 114. In such a case, after applying a voltage/current to the fusible area 102, a burned connection 300 is formed between adjacent last metals 118 of the first semiconductor build 110 (See FIG. 6B and note vertical connection 400). The advantage of using air gaps 500 is that air has a low dielectric constant (kₐᵢᵣ=1); thus it is easier to reliably burn a connection with lower current. Additionally, if air gaps 500 are used, last metal distance 138 does not necessarily have to be less than the other distances discussed in conjunction with FIGS. 1A and 1B. In addition, air gaps 500 could also be placed in dielectric 122 or etch stop 121.

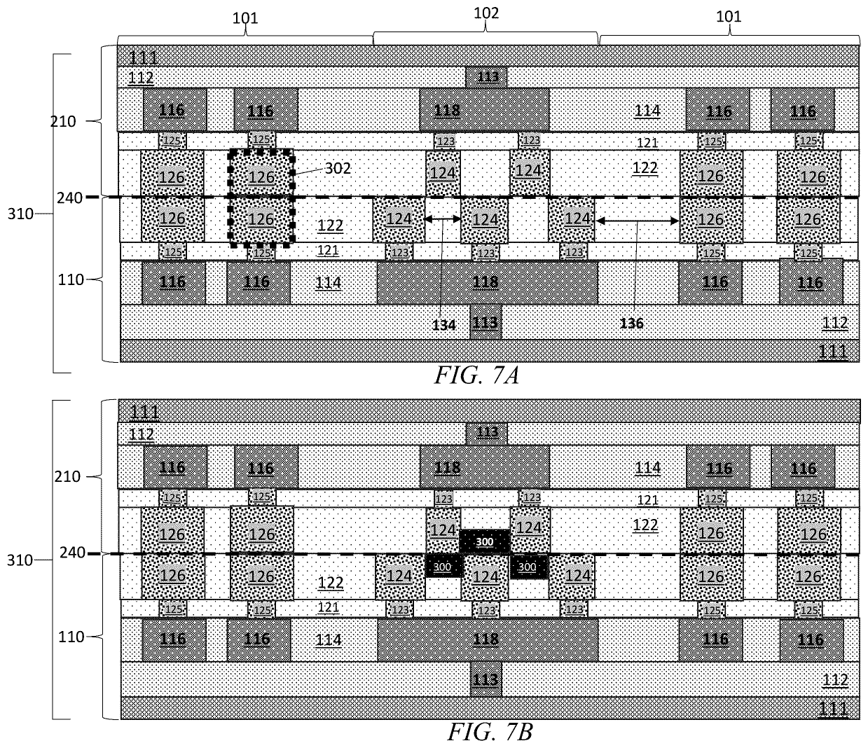

FIGS. 7A and 7B depict the bonding of semiconductor builds in which the fusible area 102 contacts 124 of the first semiconductor build 110 and the second semiconductor build 210 do not align (or stated another way, contacts 124 do not vertically overlap), while the dummy contacts 126 of each semiconductor build do align (or stated another way, dummy contacts 126 do vertically overlap). Due to the arrangement, upon heating the semiconductor builds, hybrid bonding occurs in dummy area 101. Specifically, dielectric 122 and dummy contacts 126 of the first semiconductor build 110 and second semiconductor build 210 are bonded at the interface 240. In the fusible area 102, due to the non-alignment of contacts 124 of the first semiconductor build 110 and the second semiconductor build 210, little to no bonding occurs at the interface 240 between the contact 124 of one semiconductor build and dielectric 122 of the other semiconductor build. Accordingly, a burned connection 300 can be formed upon application of sufficient voltage or current. Unlike prior embodiments, in FIG. 7A, because the surfaces 140 (seen in FIG. 3A) of the semiconductor builds do not match, there are no contact pairs formed in the fusible area 102, but only dummy contact pairs 302 in the dummy area 101. Referring to FIG. 7B, which depicts the structure of FIG. 7A after applying current, the burned connection 300 is formed along interface 240 and a portion of the dielectric 122 in each semiconductor build as it spans adjacent contacts 124.

Still referring to FIGS. 7A and 7B, an embodiment in which a single last metal 118 contacts all contacts 124 on a semiconductor build is depicted. This single last metal 118 configuration could also be used with the prior embodiments of FIGS. 1B through 6B. Conversely the embodiments of multiple last metals 118 each going to a unique contact 124 could also be used in FIGS. 7A and 7B. Also, within a hybrid bonded structure, the first semiconductor build 110 may have a last metal configuration different from the second semiconductor build 210. Furthermore, every contact 124 need not be connected to a last metal 118. An advantage of using multiple last metals 118 is that more granularity can be achieved for turning on circuits on a second semiconductor build 210. An advantage of using a single last metal 118 configuration is that there are no concerns about last metal distance relative to the contact distance 134.

While the prior figures and explanations show a burned connection 300 at a single level, it should be noted that the burned connection could span multiple levels. For example, and not by limitation, the burned connection 300 could span from last metal 118 level of the first semiconductor build 110 to the interface 240. Or from last metal 118 of the first semiconductor build 110 through the interface 240 to last metal 118 of the second semiconductor build 210.

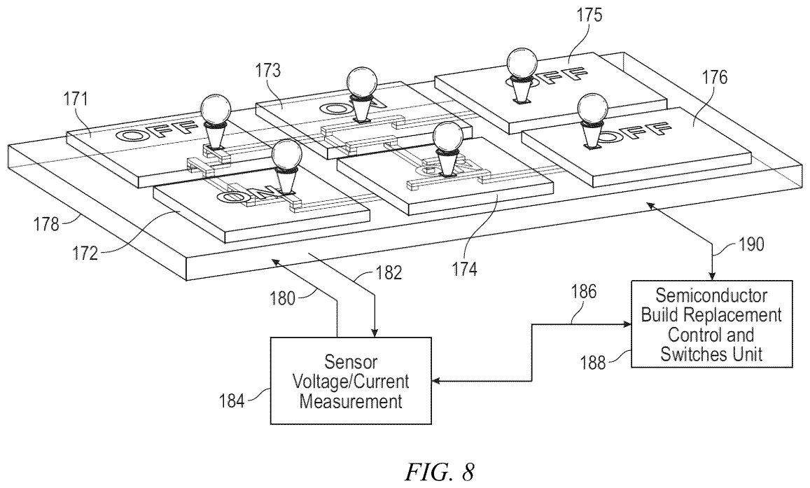

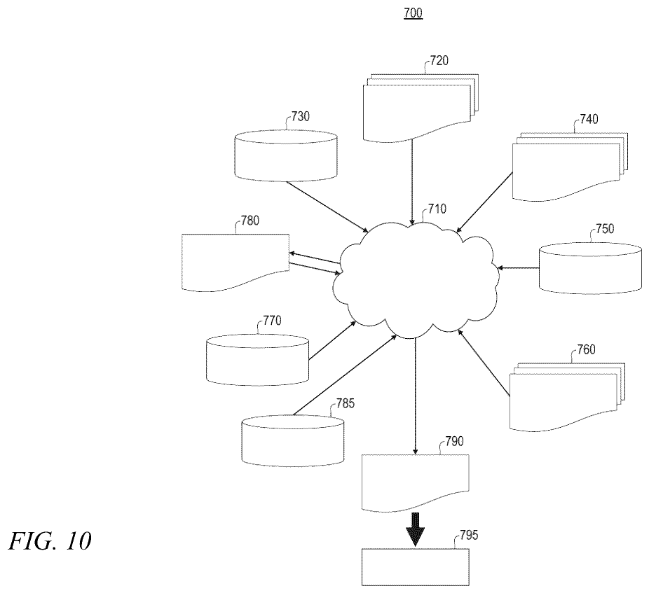

While the prior figures and explanations show two semiconductor builds it should be noted that several semiconductor builds are contemplated. FIG. 8 shows a pictorial diagram representing six semiconductor builds 171, 172, 173, 174, 175, 176 on a base semiconductor build 178. Base semiconductor build 178 can be, for example, an interposer. Base semiconductor build 178 has wiring 180 and 182 coupled to Sensor Voltage/Current Measurement 184 for measuring the resistance or conductance of electrical bonds along an electrical connected path in each semiconductor build 171, 172, 173, 174, 175, 176. The measurements may be in response to control signals over wiring 186 from Semiconductor Build Replacement Control and Switches Unit 188. The measurements may be sent over wiring 186 to Semiconductor Build Replacement Control and Switches Unit 188. Semiconductor Build Replacement Control and Switches Unit 188 has circuitry to determine if the measurements indicate a certain semiconductor build of semiconductor builds 171, 172, 173, 174 has failed or is approaching failure and responds by activating circuitry to send and receive control signals over wiring 190 to remove and replace the failed or approaching failure semiconductor build. The sensor 184 can include, for example, a digital voltmeter or digital ammeter. The unit 188 can include, for example, digital circuitry configured to compare voltage or current readings with a baseline and determine that a short (resistance zero or too low) or open (resistance infinite or too high) circuit exists (or other anomalous condition) and to cause current to be applied to “blow” fusible links to isolate the failed component and to “burn” a new connection to the new component in place of the failed component. The skilled artisan can heuristically determine what values correspond to a respective short or open depending on the application. Digital circuitry to implement the desired functionality can be synthesized in a desired logic family as explained with regard to FIG. 10 below.

If the resistance of an electrically connected path of a respective semiconductor build exceeds a limiting value, or the conductivity is below a limiting value, the respective semiconductor build can be considered as failed and can be electrically replaced with a replacement semiconductor build 175 or 176 by burning a connection (after electrically removing (isolating) the failed semiconductor build, such as with isolation circuitry which can include, for example, fusible links). The replacement semiconductor build 175 or 176 can be electrically connected in place of the failed semiconductor build. For example, where semiconductor builds 171-174 are on or active and semiconductor builds 175 and 176 are initially off, inactive or on standby, and then semiconductor build 171 fails, then semiconductor build 171 can be electrically removed and electrically replaced with semiconductor build 175 with connecting circuitry. Advantageously, the result is a functional device that can be turned on/off (depending on setup) out of what would traditionally be just passive electrical connections between the adjoined semiconductor builds. It can therefore be used as access/denial gatekeeping structure for a variety of security, back-up redundant or other programmable accessibility-based applications between the different adjoined builds.

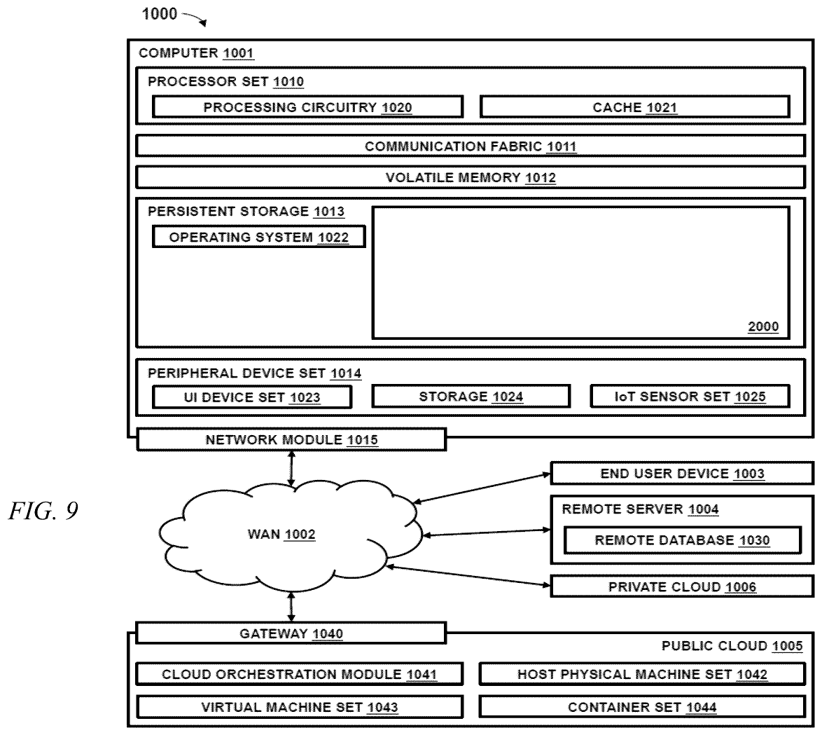

Reference should now be had to FIG. 9, which depicts a computing environment according to an embodiment of the present invention (e.g., for implementing a design process such as that of FIG. 10)

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 1000 contains an example of an environment for the execution of at least some of the computer code involved in performing the inventive methods, such as a system 2000 for semiconductor design and/or control of semiconductor fabrication (see FIG. 10). In addition to block 2000, computing environment 1000 includes, for example, computer 1001, wide area network (WAN) 1002, end user device (EUD) 1003, remote server 1004, public cloud 1005, and private cloud 1006. In this embodiment, computer 1001 includes processor set 1010 (including processing circuitry 1020 and cache 1021), communication fabric 1011, volatile memory 1012, persistent storage 1013 (including operating system 1022 and block 2000, as identified above), peripheral device set 1014 (including user interface (UI) device set 1023, storage 1024, and Internet of Things (IoT) sensor set 1025), and network module 1015. Remote server 1004 includes remote database 1030. Public cloud 1005 includes gateway 1040, cloud orchestration module 1041, host physical machine set 1042, virtual machine set 1043, and container set 1044.

COMPUTER 1001 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 1030. As is well understood in the art of computer technology, and depending upon the technology, performance of a computer-implemented method may be distributed among multiple computers and/or between multiple locations. On the other hand, in this presentation of computing environment 1000, detailed discussion is focused on a single computer, specifically computer 1001, to keep the presentation as simple as possible. Computer 1001 may be located in a cloud, even though it is not shown in a cloud in FIG. 9. On the other hand, computer 1001 is not required to be in a cloud except to any extent as may be affirmatively indicated.

PROCESSOR SET 1010 includes one, or more, computer processors of any type now known or to be developed in the future. Processing circuitry 1020 may be distributed over multiple packages, for example, multiple, coordinated integrated circuit chips. Processing circuitry 1020 may implement multiple processor threads and/or multiple processor cores. Cache 1021 is memory that is located in the processor chip package(s) and is typically used for data or code that should be available for rapid access by the threads or cores running on processor set 1010. Cache memories are typically organized into multiple levels depending upon relative proximity to the processing circuitry. Alternatively, some, or all, of the cache for the processor set may be located “off chip.” In some computing environments, processor set 1010 may be designed for working with qubits and performing quantum computing.

Computer readable program instructions are typically loaded onto computer 1001 to cause a series of operational steps to be performed by processor set 1010 of computer 1001 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 1021 and the other storage media discussed below. The program instructions, and associated data, are accessed by processor set 1010 to control and direct performance of the inventive methods. In computing environment 1000, at least some of the instructions for performing the inventive methods may be stored in block 2000 in persistent storage 1013.

COMMUNICATION FABRIC 1011 is the signal conduction path that allows the various components of computer 1001 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 1012 is any type of volatile memory now known or to be developed in the future. Examples include dynamic type random access memory (RAM) or static type RAM. Typically, volatile memory 1012 is characterized by random access, but this is not required unless affirmatively indicated. In computer 1001, the volatile memory 1012 is located in a single package and is internal to computer 1001, but, alternatively or additionally, the volatile memory may be distributed over multiple packages and/or located externally with respect to computer 1001.

PERSISTENT STORAGE 1013 is any form of non-volatile storage for computers that is now known or to be developed in the future. The non-volatility of this storage means that the stored data is maintained regardless of whether power is being supplied to computer 1001 and/or directly to persistent storage 1013. Persistent storage 1013 may be a read only memory (ROM), but typically at least a portion of the persistent storage allows writing of data, deletion of data and re-writing of data. Some familiar forms of persistent storage include magnetic disks and solid state storage devices. Operating system 1022 may take several forms, such as various known proprietary operating systems or open source Portable Operating System Interface-type operating systems that employ a kernel. The code included in block 2000 typically includes at least some of the computer code involved in performing the inventive methods.

PERIPHERAL DEVICE SET 1014 includes the set of peripheral devices of computer 1001. Data communication connections between the peripheral devices and the other components of computer 1001 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 1023 may include components such as a display screen, speaker, microphone, wearable devices (such as goggles and smart watches), keyboard, mouse, printer, touchpad, game controllers, and haptic devices. Storage 1024 is external storage, such as an external hard drive, or insertable storage, such as an SD card. Storage 1024 may be persistent and/or volatile. In some embodiments, storage 1024 may take the form of a quantum computing storage device for storing data in the form of qubits. In embodiments where computer 1001 is required to have a large amount of storage (for example, where computer 1001 locally stores and manages a large database) then this storage may be provided by peripheral storage devices designed for storing very large amounts of data, such as a storage area network (SAN) that is shared by multiple, geographically distributed computers. IoT sensor set 1025 is made up of sensors that can be used in Internet of Things applications. For example, one sensor may be a thermometer and another sensor may be a motion detector.

NETWORK MODULE 1015 is the collection of computer software, hardware, and firmware that allows computer 1001 to communicate with other computers through WAN 1002. Network module 1015 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 1015 are performed on the same physical hardware device. In other embodiments (for example, embodiments that utilize software-defined networking (SDN)), the control functions and the forwarding functions of network module 1015 are performed on physically separate devices, such that the control functions manage several different network hardware devices. Computer readable program instructions for performing the inventive methods can typically be downloaded to computer 1001 from an external computer or external storage device through a network adapter card or network interface included in network module 1015.

WAN 1002 is any wide area network (for example, the internet) capable of communicating computer data over non-local distances by any technology for communicating computer data, now known or to be developed in the future. In some embodiments, the WAN 1002 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 1003 is any computer system that is used and controlled by an end user (for example, a customer of an enterprise that operates computer 1001), and may take any of the forms discussed above in connection with computer 1001. EUD 1003 typically receives helpful and useful data from the operations of computer 1001. For example, in a hypothetical case where computer 1001 is designed to provide a recommendation to an end user, this recommendation would typically be communicated from network module 1015 of computer 1001 through WAN 1002 to EUD 1003. In this way, EUD 1003 can display, or otherwise present, the recommendation to an end user. In some embodiments, EUD 1003 may be a client device, such as thin client, heavy client, mainframe computer, desktop computer and so on.

REMOTE SERVER 1004 is any computer system that serves at least some data and/or functionality to computer 1001. Remote server 1004 may be controlled and used by the same entity that operates computer 1001. Remote server 1004 represents the machine(s) that collect and store helpful and useful data for use by other computers, such as computer 1001. For example, in a hypothetical case where computer 1001 is designed and programmed to provide a recommendation based on historical data, then this historical data may be provided to computer 1001 from remote database 1030 of remote server 1004.

PUBLIC CLOUD 1005 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 1005 is performed by the computer hardware and/or software of cloud orchestration module 1041. The computing resources provided by public cloud 1005 are typically implemented by virtual computing environments that run on various computers making up the computers of host physical machine set 1042, which is the universe of physical computers in and/or available to public cloud 1005. The virtual computing environments (VCEs) typically take the form of virtual machines from virtual machine set 1043 and/or containers from container set 1044. It is understood that these VCEs may be stored as images and may be transferred among and between the various physical machine hosts, either as images or after instantiation of the VCE. Cloud orchestration module 1041 manages the transfer and storage of images, deploys new instantiations of VCEs and manages active instantiations of VCE deployments. Gateway 1040 is the collection of computer software, hardware, and firmware that allows public cloud 1005 to communicate through WAN 1002.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 1006 is similar to public cloud 1005, except that the computing resources are only available for use by a single enterprise. While private cloud 1006 is depicted as being in communication with WAN 1002, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 1005 and private cloud 1006 are both part of a larger hybrid cloud.

Exemplary Design Process Used in Semiconductor Design, Manufacture, and/or Test

One or more embodiments make use of computer-aided semiconductor integrated circuit design simulation, test, layout, and/or manufacture. In this regard, FIG. 10 shows a block diagram of an exemplary design flow 700 used for example, in semiconductor IC logic design, simulation, test, layout, and manufacture. Design flow 700 includes processes, machines and/or mechanisms for processing design structures or devices to generate logically or otherwise functionally equivalent representations of design structures and/or devices, such as those that can be analyzed using techniques disclosed herein or the like. The design structures processed and/or generated by design flow 700 may be encoded on machine-readable storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 700 may vary depending on the type of representation being designed. For example, a design flow 700 for building an application specific IC (ASIC) may differ from a design flow 700 for designing a standard component or from a design flow 700 for instantiating the design into a programmable array, for example a programmable gate array (PGA) or a field programmable gate array (FPGA) offered by Altera® Inc. or Xilinx® Inc.

FIG. 10 illustrates multiple such design structures including an input design structure 720 that is preferably processed by a design process 710. Design structure 720 may be a logical simulation design structure generated and processed by design process 710 to produce a logically equivalent functional representation of a hardware device. Design structure 720 may also or alternatively comprise data and/or program instructions that when processed by design process 710, generate a functional representation of the physical structure of a hardware device. Whether representing functional and/or structural design features, design structure 720 may be generated using electronic computer-aided design (ECAD) such as implemented by a core developer/designer. When encoded on a gate array or storage medium or the like, design structure 720 may be accessed and processed by one or more hardware and/or software modules within design process 710 to simulate or otherwise functionally represent an electronic component, circuit, electronic or logic module, apparatus, device, or system. As such, design structure 720 may comprise files or other data structures including human and/or machine-readable source code, compiled structures, and computer executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 710 preferably employs and incorporates hardware and/or software modules for synthesizing, translating, or otherwise processing a design/simulation functional equivalent of components, circuits, devices, or logic structures to generate a Netlist 780 which may contain design structures such as design structure 720. Netlist 780 may comprise, for example, compiled or otherwise processed data structures representing a list of wires, discrete components, logic gates, control circuits, I/O devices, models, etc. that describes the connections to other elements and circuits in an integrated circuit design. Netlist 780 may be synthesized using an iterative process in which netlist 780 is resynthesized one or more times depending on design specifications and parameters for the device. As with other design structure types described herein, netlist 780 may be recorded on a machine-readable data storage medium or programmed into a programmable gate array. The medium may be a nonvolatile storage medium such as a magnetic or optical disk drive, a programmable gate array, a compact flash, or other flash memory. Additionally, or in the alternative, the medium may be a system or cache memory, buffer space, or other suitable memory.

Design process 710 may include hardware and software modules for processing a variety of input data structure types including Netlist 780. Such data structure types may reside, for example, within library elements 730 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 740, characterization data 750, verification data 760, design rules 770, and test data files 785 which may include input test patterns, output test results, and other testing information. Design process 710 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 710 without deviating from the scope and spirit of the invention. Design process 710 may also include modules for performing standard circuit design processes such as timing analysis, verification, design rule checking, place and route operations, etc.

Design process 710 employs and incorporates logic and physical design tools such as HDL compilers and simulation model build tools to process design structure 720 together with some or all of the depicted supporting data structures along with any additional mechanical design or data (if applicable), to generate a second design structure 790. Design structure 790 resides on a storage medium or programmable gate array in a data format used for the exchange of data of mechanical devices and structures (e.g. information stored in an IGES, DXF, Parasolid XT, JT, DRG, or any other suitable format for storing or rendering such mechanical design structures). Similar to design structure 720, design structure 790 preferably comprises one or more files, data structures, or other computer-encoded data or instructions that reside on data storage media and that when processed by an ECAD system generate a logically or otherwise functionally equivalent form of one or more IC designs or the like. In one embodiment, design structure 790 may comprise a compiled, executable HDL simulation model that functionally simulates the devices to be analyzed.

Design structure 790 may also employ a data format used for the exchange of layout data of integrated circuits and/or symbolic data format (e.g. information stored in a GDSII (GDS2), GL1, OASIS, map files, or any other suitable format for storing such design data structures). Design structure 790 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described herein (e.g., .lib files). Design structure 790 may then proceed to a stage 795 where, for example, design structure 790: proceeds to tape-out, is released to manufacturing, is released to a mask house, is sent to another design house, is sent back to the customer, etc.

Bulk silicon is a non-limiting example of a suitable semiconductor build material; other materials are also possible.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a semiconductor build. The replication process may involve the use of various exposing techniques and a variety of subtractive (etching) and/or additive (deposition) material processing procedures. For example, in a photolithographic process, a layer of photo-resist material may first be applied on top of a semiconductor build, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the semiconductor build underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76 (b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A hybrid bonded D-fuse structure comprising:
a first semiconductor build;
a second semiconductor build hybrid bonded to the first semiconductor build to form an interface;
a first contact in the first semiconductor build and at the interface;
a second contact in the second semiconductor build and at the interface; and
a burned connection at the interface and connecting the first and second contacts.

2. The D-fuse structure of claim 1, wherein the first contact and the second contact do not vertically overlap with each other.

3. The D-fuse structure of claim 2, further comprising:
a third contact in the second semiconductor build at the interface and spaced apart from the second contact; and
a fourth contact in the first semiconductor build at the interface and spaced apart from the first contact;
wherein neither of the first and fourth contacts vertically overlap with any of the second or third contacts.

4. The D-fuse structure of claim 3, further comprising:
a first last metal in the first semiconductor build in electrical connection with the first and fourth contacts;
a second last metal in the second semiconductor build in electrical connection with the second and third contacts.

5. The D-fuse structure of claim 1, further comprising:
a third contact in the second semiconductor build; and
a fourth contact in the first semiconductor build;
wherein the first contact vertically aligns with the third contact to form a first contact pair;
wherein the second contact vertically aligns with the fourth contact to form a second contact pair.

6. The D-fuse structure of claim 5, wherein each of the first, second, third and fourth contacts are in electrical contact with a different last metal.

7. The D-fuse structure of claim 1 further comprising:
a fusible area containing the first and second contacts;
a dummy area laterally surrounding the fusible area, the dummy area containing at least two dummy contact pairs.

8. The D-fuse structure of claim 7 wherein the at least two dummy contact pairs are nested u-shaped structures facing opposite directions.

9. The D-fuse structure of claim 7 further comprising:
a first group of the at least two dummy contact pairs are parallel to the first and second contacts and are on either side of a fusible area; and
a second group of the at least two dummy contact pairs are perpendicular to the first and second contacts and are on opposite sides of the fusible area.

10. The D-fuse structure of claim 7 wherein a distance between the first and second contact is less than a distance between the first or second contact and a closest dummy contact.

11. A hybrid bonded D-fuse structure comprising:
a first semiconductor build;
a second semiconductor build hybrid bonded to the first semiconductor build to form an interface;
a first contact in the first semiconductor build and at the interface;
a second contact in the second semiconductor build and at the interface;
a fusible area containing the first and second contacts; and
a dummy area laterally surrounding the fusible area, the dummy area containing at least two dummy contact pairs wherein a distance between the first and second contact is less than a distance between the first or second contact and a closest dummy contact.

12. The D-fuse structure of claim 11, wherein the first contact and the second contact do not vertically overlap with each other.

13. The D-fuse structure of claim 12, further comprising:
a third contact in the second semiconductor build at the interface and spaced apart from the second contact; and
a fourth contact in the first semiconductor build at the interface and spaced apart from the first contact;
wherein neither of the first and fourth contacts vertically overlap with any of the second or third contacts.

14. The D-fuse structure of claim 13, further comprising:
a first last metal in the first semiconductor build in electrical connection with the first and fourth contacts;
a second last metal in the second semiconductor build in electrical connection with the second and third contacts.

15. The D-fuse structure of claim 11, further comprising:
a third contact in the second semiconductor build; and
a fourth contact in the first semiconductor build;
wherein the first contact vertically aligns with the third contact to form a first contact pair; wherein the second contact vertically aligns with the fourth contact to form a second contact pair.

16. A method of forming a D-fuse structure, comprising:
providing a first semiconductor build comprising:
a first surface;
a first group of fusible contacts coplanar with the first surface;
a first group of dummy contacts coplanar with the first surface; and
a first group of last metals below and in electrical contact with the first group of fusible contacts;
providing a second semiconductor build comprising:
a second surface;
a second group of fusible contacts coplanar with the second surface; and
a second group of dummy contacts coplanar with the second surface; and
hybrid bonding the first surface to the second surface to form an interface.

17. The method of forming a D-fuse structure of claim 16 further comprising:
forming a burned connection between first group of fusible contacts at the interface.

18. The method of forming a D-fuse structure of claim 16 further comprising:
forming a burned connection between a first group of last metals.

19. The method of forming a D-fuse structure of claim 16 wherein the first and second groups of fusible contacts vertically overlap.

20. The method of forming a D-fuse structure of claim 16 wherein the first and second groups of fusible contacts do not vertically overlap.
